(19) United States
(12) Patent Application Publication
(10) Pub. No.: US 2016/0025529 A1
(43) Pub. Date: Jan. 28, 2016

(54) APPARATUS AND A SYSTEM FOR DETECTING A PHYSICAL VARIABLE

(71) Applicant: Infineon Technologies AG, Neubiberg (DE)

(72) Inventors: Berthold Astegher, Villach (AT); Helmut Wietschorke, Laberweinting (DE)

(21) Appl. No.: 14/802,066

(22) Filed: Jul. 17, 2015

(30) Foreign Application Priority Data
Jul. 22, 2014 (DE) 20 2014 103 355.6

(51) Int. Cl. G01D 18/00; G01L 1/16; G01R 35/00; G01L 25/00; G01R 33/07; G01R 33/09

(52) U.S. Cl. CPC G01D 18/00; G01R 33/07; G01R 33/09; G01R 35/005; G01L 25/00; G01L 1/16

(57) ABSTRACT

An apparatus for detecting a physical variable has a first sensor unit and a second sensor unit. The first sensor unit detects a physical variable on the basis of a first detection principle. Furthermore, the second sensor unit detects the physical variable on the basis of a second detection principle. In this case, the first detection principle differs from the second detection principle. The first sensor unit the second sensor unit are accommodated in a common housing.

Exemplary embodiments relate to the detection of physical variables and, in particular, to an apparatus and a system for detecting a physical variable.

Sensors for measuring physical variables are being implemented in more and more applications and in ever greater quantities. In this case, the failure safety of such sensors is of particular interest in safety-relevant applications, in particular.

There is therefore the need to provide a concept for detecting a physical variable which makes it possible to increase the reliability with which a physical variable is detected.

The subject matters of the claims take this need into account.

Some exemplary embodiments relate to an apparatus for detecting a physical variable, having a first sensor unit and a second sensor unit. The first sensor unit is designed to detect a physical variable on the basis of a first detection principle. Furthermore, the second sensor unit is designed to detect the physical variable on the basis of a second detection principle. In this case, the first detection principle differs from the second detection principle. The first sensor unit and the second sensor unit are accommodated in a common housing.

Exemplary embodiments of the present invention are explained in more detail below with reference to the accompanying figures, in which:

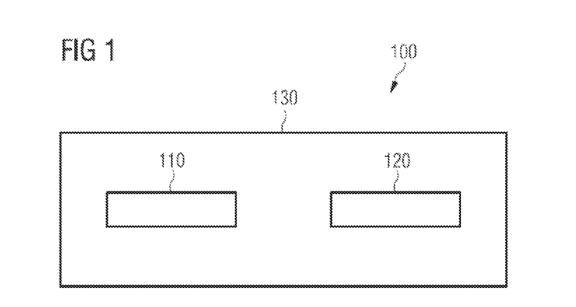

FIG. 1 shows a schematic cross section of an apparatus for detecting a physical variable;

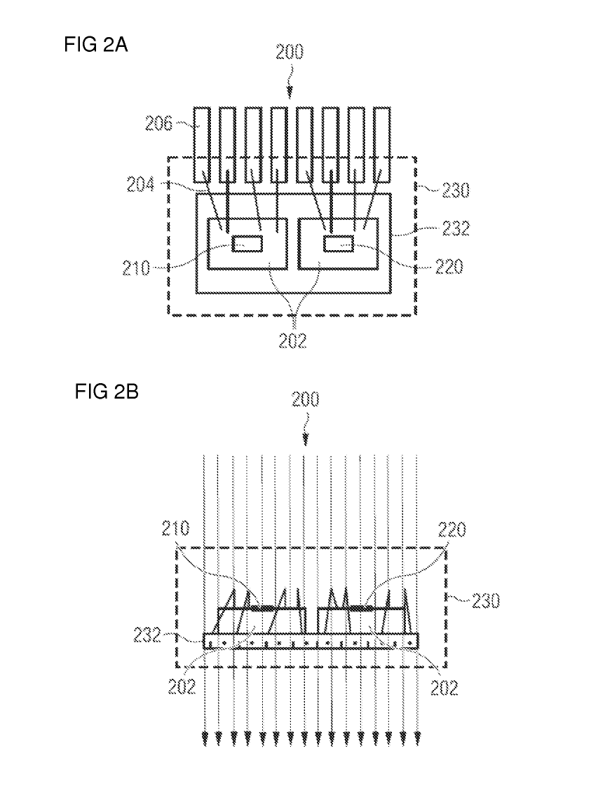

FIG. 2A shows a schematic plan view of an apparatus for detecting a physical variable;

FIG. 2B shows a schematic side view of the apparatus for detecting a physical variable from FIG. 2A;

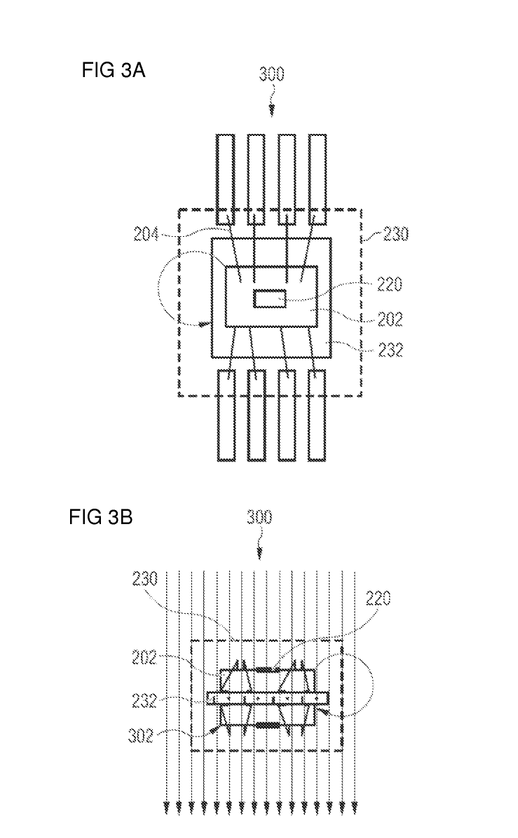

FIG. 3A shows a schematic plan view of an apparatus for detecting a physical variable;

FIG. 3B shows a schematic side view of the apparatus for detecting a physical variable from FIG. 3A;

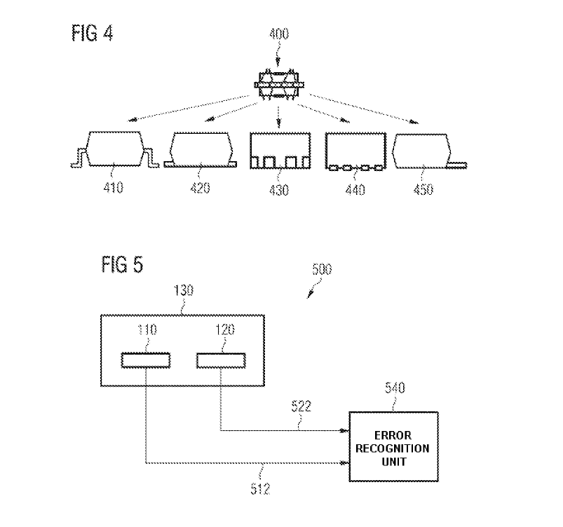

FIG. 4 shows a schematic illustration of different possible housings; and

FIG. 5 shows a schematic illustration of a system for detecting a physical variable.

Various exemplary embodiments are now described in more detail with reference to the accompanying drawings which illustrate some exemplary embodiments. In the figures, the thickness dimensions of lines, layers and/or regions may be illustrated in an exaggerated manner for the sake of clarity.

In the following description of the attached figures which show only some exemplary embodiments, identical reference symbols may denote identical or comparable components. Furthermore, it is possible to use collective reference symbols for components and objects which occur several times in an exemplary embodiment or in a drawing but are described together with respect to one or more features. Components or objects which are described using identical or collective reference symbols may be designed in an identical manner with respect to individual features, a plurality of features or all features, for example their dimensions, but may possibly also be designed differently unless explicitly or implicitly revealed otherwise in the description.

Although exemplary embodiments can be modified and altered in various ways, exemplary embodiments are illustrated in the figures as examples and are described in detail therein. However, it is clarified that the intention is not to restrict exemplary embodiments to the respectively disclosed forms but rather that exemplary embodiments are intended to cover all functional and/or structural modifications, equivalents and alternatives which are in the scope of the invention. Identical reference symbols denote identical or similar elements in the entire description of the figures.

It is noted that an element which is referred to as being “connected” or “coupled” to another element may be connected or coupled to the other element directly or there may be intermediate elements. In contrast, if an element is referred to as being “directly connected” or “directly coupled” to another element, there are no intermediate elements. Other terms which are used to describe the relationship between elements should be interpreted in a similar manner (for example “between” in comparison with “directly in between”, “adjacent” in comparison with “directly adjacent” etc.).

The terminology used herein is used only to describe particular exemplary embodiments and is not intended to restrict the exemplary embodiments. As used herein, the singular forms “a” and “the” are also intended to include the plural forms unless clearly indicated otherwise by the context. Furthermore, it is clarified that the expressions such as “comprises”, “comprising”, “has” and/or “having”, as used herein, indicate the presence of said features, integers, steps, workflows, elements and/or components but do not exclude the presence or the addition of one or more features, integers, steps, workflows, elements, components and/or groups thereof.

Unless defined otherwise, all of the terms (including technical and scientific terms) used herein have the same meaning as that attributed to them by a person of average skill in the art in the field to which the exemplary embodiments belong. Furthermore, it is clarified that expressions, for example those which are defined in generally used dictionaries, should be interpreted as if they had the meaning consistent with their meaning in the context of the relevant technology and should not be interpreted in an idealized or excessively formal sense unless expressly defined herein.

FIG. 1 shows an apparatus for detecting a physical variable according to one exemplary embodiment. The apparatus 100 has a first sensor unit 110 and a second sensor unit 120. The first sensor unit 110 detects a physical variable on the basis of a first detection principle. Furthermore, the second sensor unit detects the physical variable on the basis of a second detection principle. In this case, the first detection principle differs from the second detection principle. The first sensor unit 110 and the second sensor unit 120 are accommodated in a common housing 130.

The practice of detecting the same physical variable using two sensor units which operate on the basis of different detection principles makes it possible to considerably reduce the likelihood of an incorrect behavior of the two sensor units at the same time. This makes it possible to considerably improve the reliability with which the physical variable is detected.

The described concept can be used to detect or measure different physical variables. For example, the physical variable to be detected may be a magnetic field at the location of the apparatus 100 or a pressure of a gas or liquid.

The first sensor unit 110 and/or the second sensor unit 120 may output an analog or digital sensor signal having a voltage or current proportional to an absolute or relative value of the physical variable to be detected at the location of the apparatus 100. Alternatively, a sensor signal provided by the first sensor unit 110 or the second sensor unit 120 may have information relating to an absolute or relative value of the physical variable to be detected. For example, the first sensor unit may output a first sensor signal having information relating to the physical variable detected on the basis of the first detection principle, and the second sensor unit may output a second sensor signal having information relating to the physical variable detected on the basis of the second detection principle.

Depending on the physical variable to be detected, the sensor units may implement various different detection principles. For example, two detection principles differ if the physical effects used for detection differ from one another.

For example, the first sensor unit 110 may have a Hall element which detects a magnetic field on the basis of the Hall effect, and the second sensor unit 120 may have a magnetoresistive element which detects the magnetic field on the basis of the giant magnetoresistance effect, on the basis of the magnetic tunnel resistance effect or on the basis of the anisotropic magnetoresistive effect if the physical variable to be detected is a magnetic field. In other words, the first sensor unit 110 may be a Hall sensor, for example, and the second sensor unit 120 may be a magnetoresistive sensor (XMR sensor).

Alternatively, the first sensor unit 110 may have, for example, a giant magnetoresistance element which detects a magnetic field on the basis of the giant magnetoresistance effect, and the second sensor unit 120 may have a magnetic tunnel resistance element which detects the magnetic field on the basis of the magnetic tunnel resistance effect. In other words, the first sensor unit 110 may be a giant magnetoresistance sensor (GMR sensor), for example, and the second sensor unit 120 may be a magnetic tunnel resistance sensor (TMR sensor). In both examples, the two sensor units use different detection principles to detect the physical variable.

For example, the first sensor unit 110 may have a piezoelectric pressure element which detects a pressure on the basis of the piezoelectric effect, and the second sensor unit 120 may have a capacitive pressure element which detects a pressure on the basis of a capacitance which can be changed by pressure if the physical variable to be detected is a pressure. In other words, the first sensor unit 110 may be a piezoelectric pressure sensor, for example, and the second sensor unit 120 may be a capacitive pressure sensor. In this example too, the two sensor units use different detection principles to detect the physical variable. The common housing 130 may have, for example, one or more access openings in order to allow access to the first sensor unit 110 and to the second sensor unit 120 for a gas or liquid to be analyzed.

The first sensor unit 110 and the second sensor unit 120 are arranged in a common housing (package). For example, the common housing at least partially surrounds the first sensor unit 110 and at least partially surrounds the second sensor unit 120. For example, the two sensor units may be protected from the environment by a common housing part at least on one side or may be at least partially surrounded by molding compound. For example, the common housing may have molding compound which at least partially or completely surrounds one or more semiconductor chips of the first sensor unit 110 and of the second sensor unit 120.

The common housing may be, for example, a surface-mounted device (SMD) gullwing, a surface-mounted device flat lead, a leadless QFN (quad flat no leads), a leadless TSLP (thin small leadless package) or a P-SSO (plastic small single outline).

For example, the common housing may be a surface-mounted device gullwing, with the result that it is possible to easily monitor the solder joints at the leads. Alternatively, it is possible to use, for example, a leadless TSLP (thin small leadless package) in order to make it possible to use a small amount of space.

The first sensor unit 110 and/or the second sensor unit 120 may be semiconductor-based sensor units, for example. A semiconductor-based sensor unit is, for example, a sensor unit which is implemented on a semiconductor chip. A semiconductor chip may have, for example, a semiconductor substrate (for example silicon, silicon carbide or gallium arsenide) and one or more electrically conductive and/or electrically insulating layers on the semiconductor substrate (wiring planes of the chip).

The first sensor unit 110 and the second sensor unit 120 may be implemented on a common semiconductor chip. As a result, the two sensor units can be produced together. This makes it possible to reduce the production costs, for example. The common semiconductor chip may be at least partially (for example only on one side or completely apart from solder pads) or completely surrounded by molding compound of the common housing, for example.

Alternatively, the first sensor unit 110 and the second sensor unit 120 may be implemented on different semiconductor chips. As a result, the respective production processes can be adapted to the different sensor units and their requirements. The two semiconductor chips may be at least partially (for example only on one side or completely apart from solder pads) or completely surrounded by molding compound of the common housing, for example.

For example, the semiconductor chip of the first sensor unit 110 and the semiconductor chip of the second sensor unit 120 may be arranged beside one another on the same side of a common leadframe.

FIGS. 2A and 2B show an example of an apparatus 200 for detecting a magnetic field B, having two sensor units on two different sensor chips 202 which are mounted side-by-side. In this case, the first sensor unit has a first sensor element 210 and the second sensor unit has a second sensor element 220 (for example Hall plate). The two semiconductor chips are arranged on a common leadframe 232 (carrier strip). The first sensor unit 210 and the second sensor unit 220 are connected, via a plurality of connections 204, to a plurality of lead fingers 204 (connection fingers) which project from a common housing in order to enable an electrical connection to an external device. In this example, the common housing (for example the molding compound of the housing) completely surrounds the two sensor devices or sensor units, as is indicated by the dashed line of the housing contour 230.

On account of the short distance between the first sensor unit and the second sensor unit in the common housing, the magnetic fields B1, B2 (see magnetic field lines indicated) at the two sensor units do not differ or scarcely differ.

The apparatus 200 may optionally comprise one or more additional properties corresponding to one or more aspects which have been described in connection with the described concept or in connection with one or more of the above or following exemplary embodiments.

Alternatively, the semiconductor chip of the first sensor unit and the semiconductor chip of the second sensor unit may be arranged on opposite different sides of a common leadframe.

FIGS. 3A and 3B show an example of an apparatus 300 for detecting a magnetic field B, having two sensor units on two different sensor chips 202. The implementation of the apparatus 300 is similar to the apparatus shown in FIGS. 2A and 2B, but the two chips having the two sensor units are mounted on two opposite sides of a common leadframe 232 (can be clearly seen in FIG. 3B). The chips are therefore arranged on the top and bottom of the leadframe 232.

FIG. 3B shows a side view of a possible chip-leadframe-chip stack.

For example, a Hall sensor 220 (for example with a Hall element) is mounted on the upper side and a GMR sensor is mounted on the lower side as redundant sensors 202.

The apparatus 300 may optionally comprise one or more additional properties corresponding to one or more aspects which have been described in connection with the described concept or in connection with one or more of the above or following exemplary embodiments.

FIGS. 2A, 2B, 3A and 3B show, for example, exemplary embodiments having redundant sensors which use different sensor technologies and are arranged on different chips (for example side-by-side or front face upward and front face downward, for example opposite).

FIG. 4 shows different examples of housings which can be used by a sensor (having at least two sensor units) with different sensor principles. For example, a sensor, as is shown in FIG. 3B, having a chip-leadframe-chip stack may be accommodated in a standard SMD housing (gullwing or flat lead), a leadless SMD housing (for example QFN), a leadless housing (TSLP) or a housing with through-hole leads (P-SSO).

FIG. 4 shows, as examples of common housings, a surface-mounted device gullwing 410, a surface-mounted device flat lead 420, a leadless QFN 430 (quad flat no leads), a leadless TSLP 440 (thin small leadless package) and a P-SSO 450 (plastic small single outline).

FIG. 5 shows a system for detecting a physical variable according to one exemplary embodiment. The system 500 comprises an apparatus for detecting a physical variable according to the proposed concept or according to one of the exemplary embodiments described above or below. The system 500 also comprises an error recognition unit 540 which recognizes an error in the first sensor unit or the second sensor unit on the basis of at least one first sensor signal 512 provided by the first sensor unit and/or at least one second sensor signal 522 provided by the second sensor unit.

The practice of detecting the same physical variable using two sensor units which operate on the basis of different detection principles makes it possible to considerably reduce the likelihood of an incorrect behavior of the two sensor units at the same time. This makes it possible to considerably improve the reliability with which the physical variable is detected. Furthermore, it is possible to detect an incorrect behavior of one of the two sensor units.

The error recognition unit 540 may be an independent unit or may be part of a microcontroller, a control device (for example an electronic control unit ECU or an engine controller of a vehicle), a processor or a computer or part of a computer program or software package which runs on a microcontroller, a control device, a processor or a computer.

The error recognition unit may also optionally be arranged on the chip 130. In the case of such a system, the error recognition unit can decide to overwrite sensor signals 512 and/or 522 or to declare them invalid. Alternatively, a sensor signal could also no longer be output and an error status could be signaled to a superordinate unit, for example ECU, microcontroller.

For example, the error recognition unit 540 may recognize an error on the basis of a comparison of the first sensor signal 512 with the second sensor signal 522. For example, the two sensor units may output sensor signals permanently or at regular intervals, which sensor signals are compared with one another by the error recognition unit 540 permanently or at regular intervals.

For example, the error recognition unit 540 may recognize an error in one of the two sensor units if the first sensor signal 512 differs from the second sensor signal 522 in a comparison by more than a predefined limit value, threshold value or tolerance value.

Alternatively, the system 500 may use only a selected one of the two sensor units to detect the physical variable, for example the first sensor unit. If the error recognition unit 540 recognizes an error in the selected sensor unit (the first sensor unit) on the basis of the sensor signal output by the selected sensor unit (for example if signals are absent), a sensor unit which has not been selected, for example the second sensor unit, can be activated in order to detect the physical variable and/or confirm the recognized error.

Optionally, the selected sensor unit may also recognize an error, for example, by virtue of the fact that a value of the measured variable is above or below a threshold value. For applications in which an air gap between the sensor unit and a rotor (magnetic element) is measured, an indication that position tolerances have been exceeded may possibly result in the case of an excessively small magnetic field measured.

For example, the error recognition unit may be designed to recognize a change in an air gap between the common housing and a magnetic element (for example rotor, electromagnet, permanent magnet) on the basis of at least one first sensor signal 512 provided by the first sensor unit and/or at least one second sensor signal 522 provided by the second sensor unit. An increase or a reduction in the air gap may be recognized as a change.

More details and aspects are described in connection with the described concept or in connection with one or more of the above or following exemplary embodiments. The system 500 may optionally comprise one or more additional properties corresponding to one or more aspects which have been described in connection with the described concept or in connection with one or more of the above or following exemplary embodiments.

Some exemplary embodiments relate to a method for detecting a physical variable. The method comprises detecting a physical variable on the basis of a first detection principle by means of a first sensor unit and detecting the physical variable on the basis of a second detection principle by means of a second sensor unit. In this case, the first detection principle differs from the second detection principle. The first sensor unit and the second sensor unit may be advantageously accommodated in a common housing, for example.

The method may optionally comprise one or more additional steps corresponding to one or more aspects which have been described in connection with the described concept or in connection with one or more exemplary embodiments.

Some exemplary embodiments relate to a redundant magnetic field sensor having different sensor principles (for example Hall, XMR). More and more redundant systems are desired in vehicle sensor systems, with the result that, if one sensor fails, a backup sensor can directly undertake the function of the failed sensor. The proposed concept can construct a completely redundant sensor system having different sensors (sensor units). In order to increase the safety level of single-housing products, different sensor principles can be used (for example Hall GMR, GMR-AMR), for example, in order to avoid jointly caused errors.

Different reliability classes, for example, may be considered under the safety level (for example automotive safety integrity level ASIL, fault in time rate, FIT rate). For example, for a steering angle measurement which determines a steering angle in a vehicle for instance, a different reliability may be required at speeds of up to 10 km/h than for speeds above this threshold.

The described concept is not restricted, for example, to pure magnetic field sensors which determine the absolute value of the B field. This equally applies to speed and/or angle sensors, for example.

For example, the proposed concept may avoid technology-dependent dependencies in a magnetic field sensor system by measuring the magnetic field using different sensor technologies (for example Hall v. XMR). In other words, a common cause of an error can be recognized. If a proposed sensor system is exposed to an interfering variable, the different implementation of the sensor units means that the two sensor units react differently thereto, with the result that measured values appearing to be plausible on account of the common cause can be recognized as incorrect. For example, if one technology (for example Hall) fails on account of any event, the other technology (for example GMR or AMR) can enable the further function of the product. This could enable, for example, full redundancy for vehicle products (for example FUSI, functional safety, functional safety in an ABS system).

According to one aspect, a magnetic field can be measured with a product in a (single) semiconductor housing using different sensor principles (for example Hall and XMR).

A sensor product according to the proposed concept could be recognized, for example, from the use of different chips (for example micro-electromechanical system MEMS technologies) having different MEMS sensor elements on the chips.

The features disclosed in the above description, the following claims and the attached figures may be important and may be implemented, in their different configurations, both individually and in any desired combination for the purpose of implementing an exemplary embodiment.

Although some aspects have been described in connection with an apparatus, it goes without saying that these aspects are also a description of the corresponding method, with the result that a block or a component of an apparatus can also be understood as meaning a corresponding method step or a feature of a method step. In a similar manner, aspects which have been described in connection with a method step or as a method step are also a description of a corresponding block or detail or feature of a corresponding apparatus.

Depending on particular implementation requirements, exemplary embodiments of the invention may be implemented using hardware or software. Implementation can be carried out using a digital storage medium, for example a floppy disk, a DVD, a Blu-ray disc, a CD, a ROM, a PROM, an EPROM, an EEPROM or a flash memory, a hard disk or another magnetic or optical memory which stores electronically readable control signals which interact or can interact with a programmable hardware component in such a manner that the respective method is carried out.

A programmable hardware component may be formed by a processor, a computer processor (CPU=central processing unit), a graphics processor (GPU=graphics processing unit), a computer, a computer system, an application-specific integrated circuit (ASIC), an integrated circuit (IC), a system on chip (SOC), a programmable logic element or a field programmable gate array (FPGA) with a microprocessor.

The digital storage medium may therefore be machine-readable or computer-readable. Some exemplary embodiments therefore comprise a data storage medium having electronically readable control signals which are able to interact with a programmable computer system or a programmable hardware component in such a manner that one of the methods described herein is carried out. An exemplary embodiment is therefore a data storage medium (or a digital storage medium or a computer-readable medium) on which the program for carrying out one of the methods described herein is recorded.

Exemplary embodiments of the present invention can generally be implemented as a program, firmware, a computer program or a computer program product having a program code or as data, the program code or the data being effective to the effect that it/they carry out one of the methods when the program runs on a processor or a programmable hardware component. The program code or the data may also be stored on a machine-readable carrier or data storage medium, for example. The program code or the data may be, inter alia, in the form of source code, machine code or byte code and in the form of another intermediate code.

Another exemplary embodiment is also a data stream, a signal sequence or a sequence of signals which constitute(s) the program for carrying out one of the methods described herein. The data stream, the signal sequence or the sequence of signals may be configured, for example, to the effect that it/they is/are transferred via a data communication connection, for example via the Internet or another network. Exemplary embodiments are therefore also signal sequences which represent data and are suitable for transmission via a network or a data communication connection, the data representing the program.

A program according to one exemplary embodiment may implement one of the methods during its execution, for example, by reading memory locations or writing a data item or a plurality of data items to said memory locations, thus possibly causing switching operations or other operations in transistor structures, in amplifier structures or in other electrical, optical, or magnetic components or components operating according to another functional principle. Accordingly, data, values, sensor values or other information can be acquired, determined or measured by a program by reading a memory location. A program can therefore acquire, determine or measure variables, values, measurement variables and other information by reading one or more memory locations and can effect, cause or carry out an action and control other devices, machines and components by writing to one or more memory locations.

The exemplary embodiments described above are only an illustration of the principles of the present invention. It goes without saying that modifications and variations of the arrangements and details described herein will be apparent to other experts. Therefore, the intention is for the invention to be restricted only by the scope of protection of the patent claims below and not by the specific details which were presented herein using the description and the explanation of the exemplary embodiments.

1. An apparatus for detecting a physical variable, having the following features:
a first sensor unit which is designed to detect a physical variable on the basis of a first detection principle; and
a second sensor unit which is designed to detect the physical variable on the basis of a second detection principle, the first detection principle differing from the second detection principle, and the first sensor unit and the second sensor unit being accommodated in a common housing.

2. The apparatus as claimed in claim 1, the first sensor unit being a first semiconductor-based sensor unit and the second sensor unit being a second semiconductor-based sensor unit.

3. The apparatus as claimed in claim 1, the physical variable being a magnetic field.

4. The apparatus as claimed in claim 1, the first sensor unit having a Hall element which is designed to detect a magnetic field on the basis of the Hall effect.

5. The apparatus as claimed in claim 1, the second sensor unit having a magnetoresistive element which is designed to detect a magnetic field on the basis of the giant magnetoresistance effect, the magnetic tunnel resistance effect or the anisotropic magnetoresistive effect.

6. The apparatus as claimed in claim 1, the physical variable being a pressure.

7. The apparatus as claimed in claim 1, the first sensor unit having a piezoelectric pressure element which is designed to detect a pressure on the basis of the piezoelectric effect.

8. The apparatus as claimed in claim 1, the second sensor unit having a capacitive pressure element which is designed to detect a pressure on the basis of a capacitance which can be changed by pressure.

9. The apparatus as claimed in claim 1, the first sensor unit and the second sensor unit being implemented on different semiconductor chips.

10. The apparatus as claimed in claim 9, the semiconductor chip of the first sensor unit and the semiconductor chip of the second sensor unit being arranged beside one another on the same side of a common leadframe or being arranged opposite one another on different sides of a common leadframe.

11. The apparatus as claimed in claim 1, the first sensor unit and the second sensor unit being implemented on the same semiconductor chip.

12. The apparatus as claimed in claim 1, the common housing having molding compound which at least partially surrounds one or more semiconductor chips of the first sensor unit and of the second sensor unit.

13. The apparatus as claimed in claim 1, the common housing being a surface-mounted device gullwing, a surface-mounted device flat lead, a leadless QFN, a leadless TSLP or a P-SSO.

14. The apparatus as claimed in claim 1, the first sensor unit being designed to output a first sensor signal having information relating to the physical variable detected on the basis of the first detection principle, and the second sensor unit being designed to output a second sensor signal having information relating to the physical variable detected on the basis of the second detection principle.

15. A system for detecting a physical variable, having the following features:
an apparatus as claimed in claim 1; and
an error recognition unit which is designed to recognize an error in the first sensor unit and/or in the second sensor unit on the basis of at least one first sensor signal provided by the first sensor unit and/or at least one second sensor signal provided by the second sensor unit.

16. The system as claimed in claim 15, the error recognition unit being designed to recognize an error on the basis of a comparison of the first sensor signal with the second sensor signal.

17. The system as claimed in claim 15, the error recognition unit being designed to recognize a change in an air gap between the common housing and a magnetic element on the basis of at least one first sensor signal provided by the first sensor unit and/or at least one second sensor signal provided by the second sensor unit.
